(19) United States
(12) Patent Application Publication
(10) Pub. No.: US 2026/0190963 A1
(43) Pub. Date: Jul. 2, 2026

(54) SELF ALIGN SPACER CUT PROCESS

(71) Applicant: International Business Machines Corporation, Armonk, NY (US)

(72) Inventors: Nargess Arabchi, Slingerlands, NY (US); Chanro Park, Clifton Park, NY (US); Lawrence Alfred Clevenger, Saratoga Springs, NY (US)

(21) Appl. No.: 19/007,891

(22) Filed: Jan. 2, 2025

(51) Int. Cl. H01L 21/768; H01L 23/528

(52) U.S. Cl. CPC H10W 20/098; H10W 20/064; H10W 20/43

(57) ABSTRACT

Methods of filling a gap in a semiconductor structure are presented. A titanium nitride and sacrificial silicon nitride spacer is deposited onto a line pattern comprising a trench between two lines of the line pattern. The titanium nitride and sacrificial silicon nitride spacer is etched to leave titanium nitride and sacrificial silicon nitride spacer covering sides of the two lines within the trench. An organic planarization layer is applied over the line pattern and the titanium nitride and sacrificial silicon nitride spacer. A pillar cut is cut through the organic planarization layer and into the trench to form a gap within the trench. The gap is filled with silicon oxide.

### BACKGROUND

The disclosure relates generally to the electrical, electronic, and computer arts, and more specifically, to fabricating semiconductor devices.

Conventionally, metal traces in the interconnect layers of modern semiconductor devices are formed by a process known as self-aligned double patterning (SADP). SADP uses iterative deposition techniques to overcome the known problem that modem feature sizes are too small to be accurately formed using photolithographic techniques alone. That is, current process nodes have sub-wavelength features that are smaller than the extreme ultraviolet (EUV) wavelength that is used for photolithography. SADP uses sacrificial spacers to reduce the feature size to approximately half of the minimum size that can be achieved using EUV photolithography.

However, filling small gaps with high aspect ratios can prove equally challenging. If gaps and other features are not adequately filled, patterns are not transferred to later steps.

### SUMMARY

The illustrative examples present methods of filling a gap in a semiconductor structure. According to an illustrative embodiment, a method of filling a gap in a semiconductor structure is presented. A titanium nitride and sacrificial silicon nitride spacer is deposited onto a line pattern comprising a trench between two lines of the line pattern. The titanium nitride and sacrificial silicon nitride spacer is etched to leave titanium nitride and sacrificial silicon nitride spacer covering sides of the two lines within the trench. An organic planarization layer is applied over the line pattern and the titanium nitride and sacrificial silicon nitride spacer. A pillar cut is cut through the organic planarization layer and into the trench to form a gap within the trench. The gap is filled with silicon oxide.

According to another illustrative embodiment, a method of filling a gap in a semiconductor structure is presented. Sacrificial silicon nitride is deposited over a titanium nitride spacer to form a titanium nitride and sacrificial silicon nitride spacer on a line pattern comprising a trench between two lines of the line pattern. The titanium nitride and sacrificial silicon nitride spacer is etched to leave titanium nitride and sacrificial silicon nitride spacer covering sides of the two lines within the trench. A gap in the trench is filled with silicon oxide using a capillary effect.

According to yet another illustrative embodiment, a semiconductor structure comprises a line pattern formed of titanium nitride, the line pattern comprising a trench between two lines of the line pattern; a titanium nitride and sacrificial silicon nitride spacer covering sides of the two lines within the trench; and silicon oxide filling a gap within the trench.

In view of the foregoing, techniques of the present invention can provide substantial beneficial technical effects. For example, one or more illustrative examples provide improved gap fill in semiconductor structures. One or more illustrative examples provide improved pattern transfer. One or more illustrative examples provide cost reduction and improved throughput.

Some embodiments may not have these potential advantages, and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is an illustration of a block diagram of a semiconductor manufacturing environment in accordance with an illustrative embodiment;

FIG. 2 is an illustration of a cross-sectional view of a structure produced by filling a gap in accordance with an illustrative embodiment;

FIGS. 3A and 3B are a flowchart of a method of filling a gap in a semiconductor structure in accordance with an illustrative embodiment; and

FIG. 4 is a flowchart of a method of filling a gap in a semiconductor structure in accordance with an illustrative embodiment.

### DETAILED DESCRIPTION

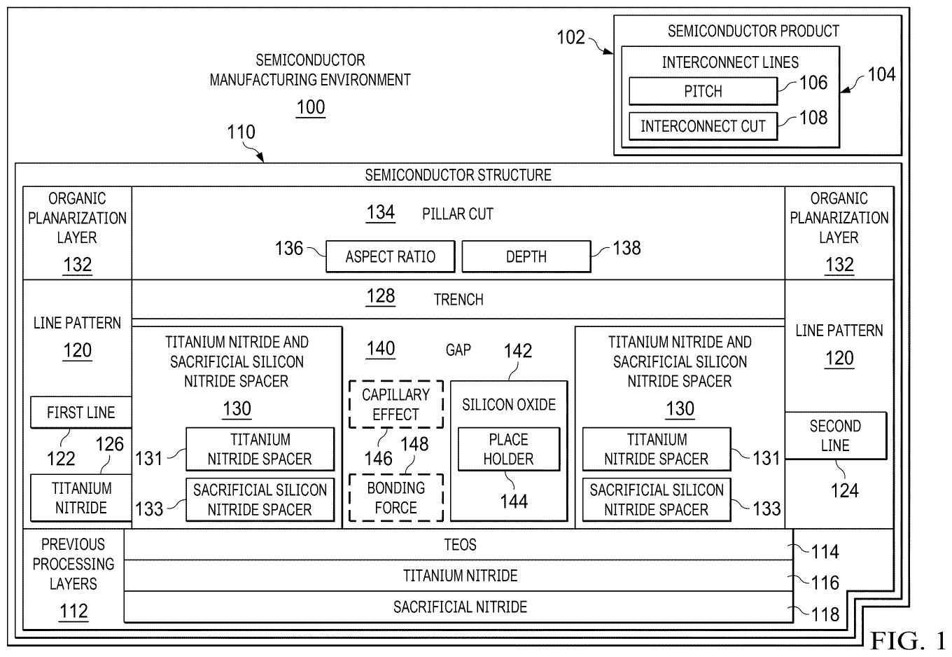

Turning now to FIG. 1, an illustration of a block diagram of a semiconductor manufacturing environment is depicted in accordance with an illustrative embodiment. Semiconductor product 102 with improved quality can be manufactured in semiconductor manufacturing environment 100. Semiconductor product 102 comprises interconnect lines 104 with pitch 106 of approximately 10 nm or less. Generation of interconnect cut 108 between interconnect lines 104 is enabled by blocking metal fill using silicon oxide 142 in gap 140.

Semiconductor structure 110 is an intermediary step in manufacturing semiconductor product 102. Semiconductor structure 110 comprises line pattern 120 formed of titanium nitride 126, line pattern 120 comprises trench 128 between two lines of line pattern 120. In this illustrative example, the two lines are first line 122 and second line 124. Semiconductor structure 110 further comprises titanium nitride and sacrificial silicon nitride spacer 130 covering sides of the two lines in trench 128. Semiconductor structure 110 further comprises silicon oxide 142 filling gap 140 within trench 128.

Silicon oxide 142 comprises place holder 144 for interconnect cut 108. Silicon oxide 142 blocks deposition of metal in the position of gap 140 to form interconnect cut 108 in subsequent processing steps.

In some illustrative examples, interconnect cut 108 is for interconnect lines 104 with pitch 106 of approximately 10 nm or less. Pitch 106 increases the difficulty of filling gap 140.

Semiconductor structure 110 further comprises organic planarization layer 132 over line pattern 120 and titanium nitride and sacrificial silicon nitride spacer 130 and within trench 128. Pillar cut 134 extends through organic planarization layer 132 and into trench 128 forming gap 140. Depth 138 of pillar cut 134 can be significantly larger than a pitch of pillar cut 134. Silicon oxide 142 is introduced to trench 128 through pillar cut 134. Pillar cut 134 has a large aspect ratio that increases the difficulty of filling gap 140. In some illustrative examples, pillar cut 134 has aspect ratio 136 of up to 17. In some illustrative examples, pillar cut has aspect ratio 136 approximately 16 nm by 100 nm in the Z direction.

Line pattern 120 is over previous processing layers 112. In this illustrative example, previous processing layers 112 comprises TEOS 114, titanium nitride 116, and sacrificial nitride 118. However, previous processing layers 112 can comprise any desirable layers.

Sacrificial silicon nitride spacer 133 is deposited over titanium nitride spacer 131 to form titanium nitride and sacrificial silicon nitride spacer 130 on line pattern 120. Titanium nitride and sacrificial silicon nitride spacer 130 is etched to leave titanium nitride and sacrificial silicon nitride spacer 130 covering sides of first line 122 and second line 124 in trench 128.

Organic planarization layer 132 is applied over line pattern 120 and titanium nitride and sacrificial silicon nitride spacer 130. Pillar cut 134 is cut through organic planarization layer 132 and into trench 128 to form gap 140 within trench 128. After cutting pillar cut 134 into organic planarization layer 132 and trench 128, pillar cut 134 and gap 140 is filled with silicon oxide 142. In some illustrative examples, filling gap 140 with silicon oxide 142 comprises performing a spin on glass deposition.

In some illustrative examples, filling gap 140 with silicon oxide 142 comprises pulling silicon oxide 142 into gap 140 using capillary effect 146. In some illustrative examples, filling gap 140 with silicon oxide 142 comprises pulling silicon oxide 142 into gap 140 using bonding force 148 between titanium nitride and sacrificial silicon nitride spacer 130 and silicon oxide 142.

After filling gap 140 with silicon oxide 142, silicon oxide 142 and organic planarization layer 132 are etched back. Silicon oxide 142 remains in gap 140. After etching back organic planarization layer 132, organic planarization layer ashing is performed to remove organic planarization layer 132 from trench 128. After organic planarization layer ashing, spacer etch back is performed to remove titanium nitride and sacrificial silicon nitride spacer 130. Additional processing is performed on semiconductor structure 110 to form semiconductor product 102 with interconnect lines 104. In some illustrative examples, the additional processing comprises depositing metal into trench 128 of line pattern 120 to form interconnect lines 104 with silicon oxide 142 forming place holder 144 for interconnect cut 108 between interconnect lines 104.

The illustrative examples improve gap fill in small structures through material selection. The illustrative examples provide efficient gap fill. Efficient gap fill refers to completely or nearly completely filling a gap. The illustrative examples improve gap fill in small structures using the material interaction between titanium nitride and sacrificial silicon nitride spacer 130 and silicon oxide 142. The illustrative examples improve fill quality for confined structures by means of enhanced interaction between selective surface interactions.

The illustrative examples provide efficient pattern transfer. Efficient pattern transfer results from efficient gap fill.

The illustrative examples provide a throughput improvement. In some illustrative examples, a spin on material deposition of silicon oxide 142 is a faster deposition than alternative deposition methods.

The illustrative examples provide cost reduction. In some illustrative examples, cost reduction is provided by reduced processing time. In some illustrative examples, cost reduction of approximately 50% can be provided by using spin on fill material.

Although silicon oxide 142 and SAC silicon nitride spacer 133 are discussed in this illustrative example, the selection of materials for efficient gap fill is applicable to variety of processes and structures in patterning as back end of line (BEOL) structures are scaled down.

In the illustrative examples, the spacer and the fill materials are chosen/modified to enhance the capillary effects. In the illustrative examples, strong bonding force 148 between the sidewall and the incoming material, silicon oxide 142, pulls the material into gap 140 by capillary effect 146 resulting in effective gap fill.

With titanium nitride and sacrificial silicon nitride spacer 130, the bond between SAC silicon nitride spacer 133 and the spin on glass (SOG), silicon oxide 142, is strong enough to pull the SOG into trench 128 for better fill. The surface bonding between the fill material, silicon oxide 142, and the surface material within the cut, sacrificial silicon nitride spacer 133, create capillary effect 146 and facilitate filling various materials into the confined features. The surface engineering enables faster gap fill methods than ALD deposition. The illustrative examples provide fast gap fill process throughput using surface engineering compared to ALD.

The silicon oxide 142 pillars formed by filling gap 140 survive the spacer etch back process due to effective gap fill with spin on glass and titanium nitride and sacrificial silicon nitride spacer 130 (SiN/SiOx surface). By surviving the spacer etch back process, the silicon oxide 142 pillars are used to form interconnect cuts.

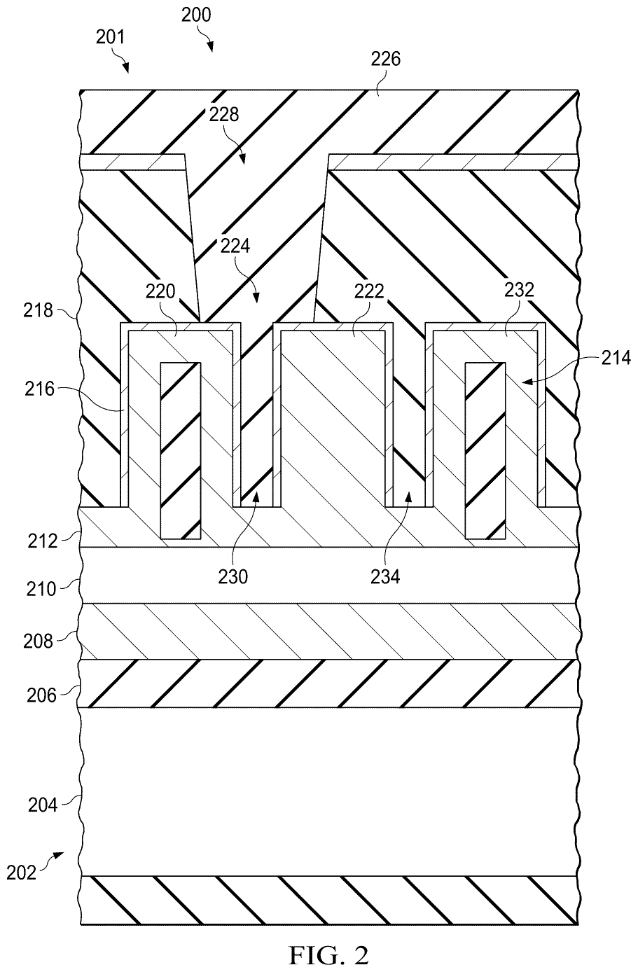

Turning now to FIG. 2, an illustration of a cross-sectional view of a structure produced by filling a gap is depicted in accordance with an illustrative embodiment. View 200 is a cross-sectional view of semiconductor structure 201. Semiconductor structure 201 can be a physical implementation of semiconductor structure 110 of FIG. 1.

Semiconductor structure 201 is an intermediary step in manufacturing a semiconductor product. Semiconductor structure 201 comprises line pattern 214 formed of titanium nitride 212. Line pattern 214 comprises trench 224 between two lines of line pattern 214. In this illustrative example, the two lines are first line 220 and second line 222. Semiconductor structure 201 further comprises titanium nitride and sacrificial silicon nitride spacer 216 covering sides of the two lines in trench 224. Semiconductor structure 201 further comprises silicon oxide 226 filling gap 230 within trench 224.

Silicon oxide 226 in gap 230 comprises a place holder for an interconnect cut. Semiconductor structure 201 further comprises organic planarization layer 218 over line pattern 214 and titanium nitride and sacrificial silicon nitride spacer 216. Organic planarization layer 218 also extends into trench 234 between second line 222 and third line 232. Organic planarization layer 218 also extends into trench 224 in a region outside of gap 230 not visible in view 200. Organic planarization layer 218 extends into trench 224 in regions into and out of the page in the current illustration.

Pillar cut 228 extends through organic planarization layer 218 and into trench 224 forming gap 230. Silicon oxide 226 is introduced to trench 224 through pillar cut 228. Pillar cut 228 has a large aspect ratio that increases the difficulty of filling gap 230. In some illustrative examples, pillar cut 228 has an aspect ratio of up to 17. In some illustrative examples, pillar cut 228 has an aspect ratio of approximately 16 nm by 100 nm in the Z direction.

Line pattern 214 is over previous processing layers 202. In this illustrative example, previous processing layers 202 comprises substrate 204, sacrificial nitride (SacN) 206, titanium nitride (TiN) 208, and TEOS 210. However, previous processing layers 202 can comprise any desirable type and quantity of layers.

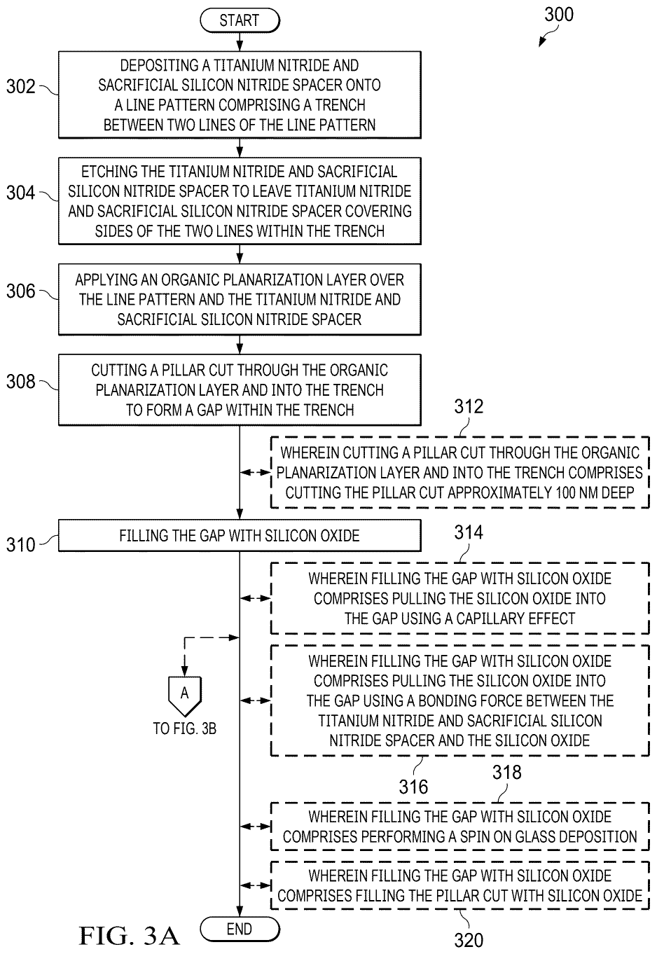

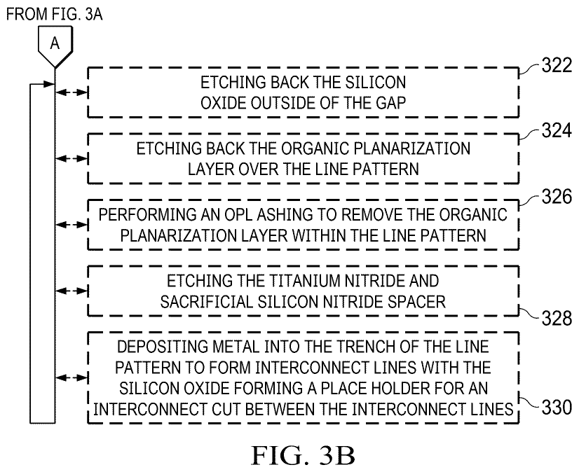

Turning now to FIGS. 3A and 3B, a flowchart of a method of filling a gap in a semiconductor structure is depicted in accordance with an illustrative embodiment. Method 300 can be used to fill gap 140 in FIG. 1. Method 300 can be used to fill gap 230 in FIG. 2.

Method 300 deposits a titanium nitride and sacrificial silicon nitride spacer onto a line pattern comprising a trench between two lines of the line pattern (operation 302). Method 300 etches the titanium nitride and sacrificial silicon nitride spacer to leave titanium nitride and sacrificial silicon nitride spacer covering sides of the two lines within the trench (operation 304). Method 300 applies an organic planarization layer over the line pattern and the titanium nitride and sacrificial silicon nitride spacer (operation 306). Method 300 cuts a pillar cut through the organic planarization layer and into the trench to form a gap within the trench (operation 308). Method 300 fills the gap with silicon oxide (operation 310). Afterwards, method 300 terminates.

In some illustrative examples, cutting a pillar cut through the organic planarization layer and into the trench comprises cutting the pillar cut approximately 100 nm deep (operation 312).

In some illustrative examples, filling the gap with silicon oxide comprises pulling the silicon oxide into the gap using a capillary effect (operation 314). In some illustrative examples, filling the gap with silicon oxide comprises pulling the silicon oxide into the gap using a bonding force between the titanium nitride and sacrificial silicon nitride spacer and the silicon oxide (operation 316).

In some illustrative examples, filling the gap with silicon oxide comprises performing a spin on glass deposition (operation 318). In some illustrative examples, filling the gap with silicon oxide comprises filling the pillar cut with silicon oxide (operation 320).

In some illustrative examples, method 300 etches back the silicon oxide outside of the gap (operation 322). In some illustrative examples, method 300 etches back the organic planarization layer over the line pattern (operation 324). In some illustrative examples, method 300 performs an OPL ashing to remove the organic planarization layer within the line pattern (operation 326).

In some illustrative examples, method 300 etches the titanium nitride and sacrificial silicon nitride spacer (operation 328). In some illustrative examples, method 300 deposits metal into the trench of the line pattern to form interconnect lines with the silicon oxide forming a place holder for an interconnect cut between the interconnect lines (operation 330).

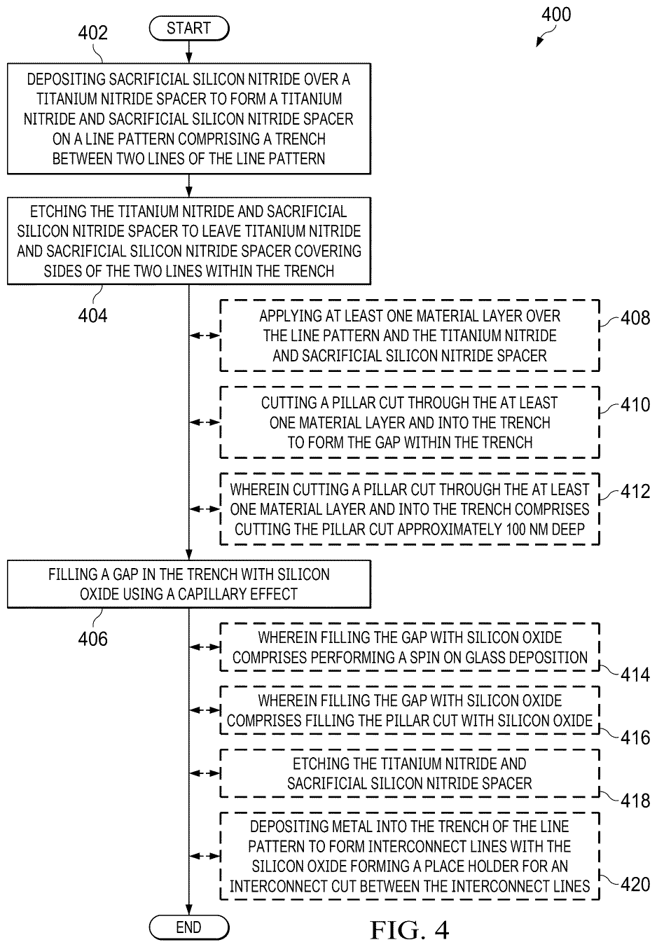

Turning now to FIG. 4 is a flowchart of a method of filling a gap in a semiconductor structure in accordance with an illustrative embodiment. Method 400 can be used to fill gap 140 in FIG. 1. Method 400 can be used to fill gap 230 in FIG. 2.

Method 400 deposits sacrificial silicon nitride over a titanium nitride spacer to form a titanium nitride and sacrificial silicon nitride spacer on a line pattern comprising a trench between two lines of the line pattern (operation 402). Method 400 etches the titanium nitride and sacrificial silicon nitride spacer to leave titanium nitride and sacrificial silicon nitride spacer covering sides of the two lines within the trench (operation 404). Method 400 fills a gap in the trench with silicon oxide using a capillary effect (operation 406). Afterwards, method 400 terminates.

In some illustrative examples, method 400 applies at least one material layer over the line pattern and the titanium nitride and sacrificial silicon nitride spacer (operation 408). In some illustrative examples, method 400 cuts a pillar cut through the at least one material layer and into the trench to form the gap within the trench (operation 410).

In some illustrative examples, cutting a pillar cut through the at least one material layer and into the trench comprises cutting the pillar cut approximately 100 nm deep (operation 412). In some illustrative examples, filling the gap with silicon oxide comprises performing a spin on glass deposition (operation 414). In some illustrative examples, filling the gap with silicon oxide comprises filling the pillar cut with silicon oxide (operation 416).

In some illustrative examples, method 400 etches the titanium nitride and sacrificial silicon nitride spacer (operation 418). In some illustrative examples, method 400 deposits metal into the trench of the line pattern to form interconnect lines with the silicon oxide forming a place holder for an interconnect cut between the interconnect lines (operation 420).

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of filling a gap in a semiconductor structure comprising:
depositing a titanium nitride and sacrificial silicon nitride spacer onto a line pattern comprising a trench between two lines of the line pattern;
etching the titanium nitride and sacrificial silicon nitride spacer to leave titanium nitride and sacrificial silicon nitride spacer covering sides of the two lines within the trench;
applying an organic planarization layer over the line pattern and the titanium nitride and sacrificial silicon nitride spacer;
cutting a pillar cut through the organic planarization layer and into the trench to form a gap within the trench; and
filling the gap with silicon oxide.

2. The method of claim 1 further comprising:
etching back the silicon oxide outside of the gap;
etching back the organic planarization layer over the line pattern; and
performing an OPL ashing to remove the organic planarization layer within the line pattern.

3. The method of claim 1 further comprising:
etching the titanium nitride and sacrificial silicon nitride spacer; and
depositing metal into the trench of the line pattern to form interconnect lines with the silicon oxide forming a place holder for an interconnect cut between the interconnect lines.

4. The method of claim 1, wherein filling the gap with silicon oxide comprises pulling the silicon oxide into the gap using a capillary effect.

5. The method of claim 1, wherein filling the gap with silicon oxide comprises pulling the silicon oxide into the gap using a bonding force between the titanium nitride and sacrificial silicon nitride spacer and the silicon oxide.

6. The method of claim 1, wherein filling the gap with silicon oxide comprises performing a spin on glass deposition.

7. The method of claim 1, wherein filling the gap with silicon oxide comprises filling the pillar cut with silicon oxide.

8. The method of claim 1, wherein cutting a pillar cut through the organic planarization layer and into the trench comprises cutting the pillar cut approximately 100 nm deep.

9. A method of filling a gap in a semiconductor structure comprising:
depositing sacrificial silicon nitride over a titanium nitride spacer to form a titanium nitride and sacrificial silicon nitride spacer on a line pattern comprising a trench between two lines of the line pattern;
etching the titanium nitride and sacrificial silicon nitride spacer to leave titanium nitride and sacrificial silicon nitride spacer covering sides of the two lines within the trench; and
filling a gap in the trench with silicon oxide using a capillary effect.

10. The method of claim 9, wherein filling the gap with silicon oxide comprises performing a spin on glass deposition.

11. The method of claim 9 further comprising:
applying at least one material layer over the line pattern and the titanium nitride and sacrificial silicon nitride spacer; and
cutting a pillar cut through the at least one material layer and into the trench to form the gap within the trench.

12. The method of claim 11, wherein filling the gap with silicon oxide comprises filling the pillar cut with silicon oxide.

13. The method of claim 11, wherein cutting a pillar cut through the at least one material layer and into the trench comprises cutting the pillar cut approximately 100 nm deep.

14. The method of claim 9 further comprising:
etching the titanium nitride and sacrificial silicon nitride spacer; and
depositing metal into the trench of the line pattern to form interconnect lines with the silicon oxide forming a place holder for an interconnect cut between the interconnect lines.

15. A semiconductor structure comprising:
a line pattern formed of titanium nitride, the line pattern comprising a trench between two lines of the line pattern;
a titanium nitride and sacrificial silicon nitride spacer covering sides of the two lines within the trench; and
silicon oxide filling a gap within the trench.

16. The semiconductor structure of claim 15, wherein the silicon oxide comprises a place holder for an interconnect cut.

17. The semiconductor structure of claim 16, wherein the interconnect cut is for interconnect lines with a pitch of approximately 10 nm or less.

18. The semiconductor structure of claim 15 further comprising:
an organic planarization layer over the line pattern and titanium nitride and sacrificial silicon nitride spacer and within the trench; and
a pillar cut extending through the organic planarization layer and into the trench forming the gap.

19. The semiconductor structure of claim 18, wherein the pillar cut has an aspect ratio of up to 17.

20. The semiconductor structure of claim 18, wherein the pillar cut has an aspect ratio approximately 16 nm by 100 nm in the Z direction.
